(19) United States
(12) Patent Application Publication
(10) Pub. No.: US 2025/0255039 A1
(43) Pub. Date: Aug. 7, 2025

(54) LIGHT EMITTING ELEMENT AND PRODUCTION METHOD THEREFOR

(71) Applicant: TOYODA GOSEI CO., LTD., Kiyosu-shi (JP)

(72) Inventor: Koichi GOSHONOO, Kiyosu-shi (JP)

(21) Appl. No.: 19/042,627

(22) Filed: Jan. 31, 2025

(30) Foreign Application Priority Data
Feb. 5, 2024 (JP) 2024-015571

(51) Int. Cl. H10H 20/813; H10H 20/01; H10H 20/825

(52) U.S. Cl. CPC H10H 20/8131; H10H 20/0137; H10H 20/017; H10H 20/825

(57) ABSTRACT

A method for producing a light emitting element, includes: forming, over a substrate, an n-type layer; forming, over the n-type layer, a first active layer; forming, over the first active layer, a first intermediate layer; forming, over the first intermediate layer, a second active layer having a band gap energy different from the first active layer; forming a first groove having a depth reaching the first intermediate layer from a side of the second active layer; forming a p-type layer containing a p-type Group III nitride semiconductor over the second active layer, over a bottom surface of the first groove, and over a side surface of the first groove; and etching the p-type layer in a vicinity of a region that connects a region over the second active layer and a region over the bottom surface of the first groove to form a first recessed portion.

### CROSS-REFERENCE TO RELATED APPLICATION

This application is based on and claims priority under 35 USC 119 from Japanese Patent Application No. 2024-015571 filed on Feb. 5, 2024.

### TECHNICAL FIELD

The present invention relates to a light emitting element and a production method therefor.

### BACKGROUND ART

In recent years, high definition of displays has been required, and a micro LED display, in which each pixel is a minute LED on the order of 1 μm to 100 μm, has attracted attention. Various full-color methods are known, and for example, a method in which three active layers emitting blue, green, and red light are sequentially stacked on the same substrate is known.

JP2021-158179A discloses a monolithic micro LED display having a plurality of pixels disposed on the same substrate. The monolithic micro LED display disclosed in JP2021-158179A includes an n-type layer, a first active layer, a first intermediate layer, a second active layer, a second intermediate layer, a third active layer, and a cap layer sequentially stacked on a substrate from a substrate side, a first recessed portion is provided from a surface side of the cap layer to the second intermediate layer, a second recessed portion is provided from the surface side of the cap layer to the first intermediate layer, a p-type layer is provided continuously on the cap layer, on a side surface and a bottom surface of the first recessed portion, and on a side surface and a bottom surface of the second recessed portion, and a p-side electrode is provided on the p-type layer in a region corresponding to an upper portion of the cap layer, a region corresponding to the first recessed portion, and a region corresponding to the second recessed portion.

### SUMMARY OF INVENTION

However, in a light emitting element in JP2021-158179A, p-type layers of sub-pixels are continuous. Therefore, when a distance between the sub-pixels is shortened by miniaturization, resistance of a region of the p-type layer that connects the sub-pixels also decreases. Then, when a certain sub-pixel is intended to emit light, the current leaks through the p-type layer to an adjacent sub-pixel, and a sub-pixel other than the sub-pixel intended to emit light may emit light. As a result, a desired emission color may not be obtained or a color purity may decrease.

The present invention has been made in view of such a background, and an object thereof is to provide a light emitting element and a method for producing a light emitting element enabling emission of light in a desired region.

An aspect of the present invention relates to a method for producing a light emitting element, including:
an n-type layer forming step of forming, on a substrate, an n-type layer containing an n-type Group III nitride semiconductor;
a first active layer forming step of forming, on the n-type layer, a first active layer having a predetermined band gap energy;
a first intermediate layer forming step of forming, on the first active layer, a first intermediate layer containing a Group III nitride semiconductor;
a second active layer forming step of forming, on the first intermediate layer, a second active layer having a band gap energy different from the band gap energy of the first active layer;
a groove forming step of forming a first groove having a depth reaching the first intermediate layer from a second active layer side;
a p-type layer forming step of forming a p-type layer containing a p-type Group III nitride semiconductor on the second active layer, on a bottom surface of the first groove, and on a side surface of the first groove; and
a p-type layer etching step of etching the p-type layer in a vicinity of a region that connects a region on the second active layer and a region on the bottom surface of the first groove to form a first recessed portion.

Another aspect of the present invention relates to a light emitting element including:
a substrate;
an n-type layer provided on the substrate and containing an n-type Group III nitride semiconductor;
a first active layer provided on the n-type layer and having a predetermined band gap energy;
a first intermediate layer provided on the first active layer and containing a Group III nitride semiconductor;
a second active layer provided on the first intermediate layer and having a band gap energy different from the band gap energy of the first active layer;
a first groove having a depth reaching the first intermediate layer from a second active layer side;
a p-type layer provided on the second active layer, on a bottom surface of the first groove, and on a side surface of the first groove, and containing a p-type Group III nitride semiconductor; and
a first recessed portion provided in the p-type layer in a vicinity of a region that connects a region on the second active layer and a region on the bottom surface of the first groove.

In the above aspect, the p-type layer is etched in the vicinity of the region that connects the region on the second active layer and the region on the bottom surface of the first groove. Therefore, the p-type layer is thinner than other regions. Alternatively, the p-type layer is physically separated. Therefore, when a certain sub-pixel is intended to emit light, it is possible to prevent current leakage to an adjacent sub-pixel through the p-type layer. As a result, only the intended sub-pixel can emit light.

As described above, according to the above aspects, it is possible to provide a light emitting element and a method for producing a light emitting element enabling emission of light in a desired region.

### BRIEF DESCRIPTION OF DRAWINGS

FIG. 1 is a diagram showing a configuration of a light emitting element according to an embodiment, which is a cross-sectional view in a direction perpendicular to a main surface of a substrate.

FIG. 2 is a plan view showing an electrode pattern of the light emitting element according to the embodiment.

FIG. 3 is an enlarged cross-sectional view showing a part of the configuration of a light emitting element according to the embodiment.

FIG. 4 is a diagram showing a step of producing the light emitting element according to the embodiment.

FIG. 5 is a diagram showing a step of producing the light emitting element according to the embodiment.

FIG. 6 is a diagram showing a step of producing the light emitting element according to the embodiment.

FIG. 7 is a diagram showing a step of producing the light emitting element according to the embodiment.

FIG. 8 is a diagram showing a step of producing the light emitting element according to the embodiment.

FIG. 9 is a diagram showing a step of producing the light emitting element according to the embodiment.

FIG. 10 is a photograph showing a light emission state of each sub-pixel.

FIG. 11 is a diagram showing a configuration of a light emitting element according to a modification of the embodiment, which is a cross-sectional view in a direction perpendicular to a main surface of a substrate.

### DETAILED DESCRIPTION OF THE INVENTION

A method for producing a light emitting element includes: an n-type layer forming step of forming, on a substrate, an n-type layer containing an n-type Group III nitride semiconductor; a first active layer forming step of forming, on the n-type layer, a first active layer having a predetermined band gap energy; a first intermediate layer forming step of forming, on the first active layer, a first intermediate layer containing a Group III nitride semiconductor; a second active layer forming step of forming, on the first intermediate layer, a second active layer having a band gap energy different from the band gap energy of the first active layer; a groove forming step of forming a first groove having a depth reaching the first intermediate layer from a second active layer side; a p-type layer forming step of forming a p-type layer containing a p-type Group III nitride semiconductor on the second active layer, on a bottom surface of the first groove, and on a side surface of the first groove; and a p-type layer etching step of etching the p-type layer in a vicinity of a region that connects a region on the second active layer and a region on the bottom surface of the first groove to form a first recessed portion.

In the above method for producing a light emitting element, the first recessed portion may have a depth smaller than a thickness of the p-type layer. In addition, the first recessed portion may have a depth in a range of −20 nm to +20 nm of a thickness of the p-type layer.

The above method for producing a light emitting element may further include: a second intermediate layer forming step of forming, on the second active layer, a second intermediate layer containing a Group III nitride semiconductor; and a third active layer forming step of forming, on the second intermediate layer, a third active layer having a band gap energy different from that of the first active layer and the second active layer, in which in the groove forming step, a second groove having a depth reaching the second intermediate layer from a third active layer side may be formed, in the p-type layer forming step, the p-type layer containing a p-type Group III nitride semiconductor may be formed on the third active layer, on the bottom surface of the first groove, on a bottom surface of the second groove, on the side surface of the first groove, and on a side surface of the second groove, and in the p-type layer etching step, the p-type layer may be etched in a vicinity of a region that connects a region on the third active layer and a region on the bottom surface of the second groove to further form a second recessed portion having a depth same as the first recessed portion.

In the p-type layer etching step, the p-type layer may be etched in a vicinity of a region that connects a region on the bottom surface of the first groove and the region on the third active layer to further form a third recessed portion having a depth same as the first recessed portion and the second recessed portion.

A light emitting element includes: a substrate; an n-type layer provided on the substrate and containing an n-type Group III nitride semiconductor; a first active layer provided on the n-type layer and having a predetermined band gap energy; a first intermediate layer provided on the first active layer and containing a Group III nitride semiconductor; a second active layer provided on the first intermediate layer and having a band gap energy different from the band gap energy of the first active layer; a first groove having a depth reaching the first intermediate layer from a second active layer side; a p-type layer provided on the second active layer, on a bottom surface of the first groove, and on a side surface of the first groove, and containing a p-type Group III nitride semiconductor; and a first recessed portion provided in the p-type layer in a vicinity of a region that connects a region on the second active layer and a region on the bottom surface of the first groove.

In the above light emitting element, the first recessed portion may have a depth smaller than a thickness of the p-type layer. In addition, the first recessed portion may have a depth in a range of −20 nm to +20 nm of a thickness of the p-type layer.

The above light emitting element may further include: a second intermediate layer provided on the second active layer and containing a Group III nitride semiconductor; a third active layer provided on the second intermediate layer and having a band gap energy different from that of the first active layer and the second active layer; and a second groove having a depth reaching the second intermediate layer from a third active layer side, in which the p-type layer may be provided on the third active layer, on the bottom surface of the first groove, on a bottom surface of the second groove, on the side surface of the first groove, and on a side surface of the second groove, and a second recessed portion having a depth same as the first recessed portion may be further provided in the p-type layer in a vicinity of a region that connects a region on the third active layer and a region on the bottom surface of the second groove.

In the above light emitting element, a third recessed portion having a depth same as the first recessed portion and the second recessed portion may be further provided in the p-type layer in a vicinity of a region that connects the region on the bottom surface of the first groove and the region on the third active layer.

### EMBODIMENT

### 1. Overview of Light Emitting Element According to Embodiment

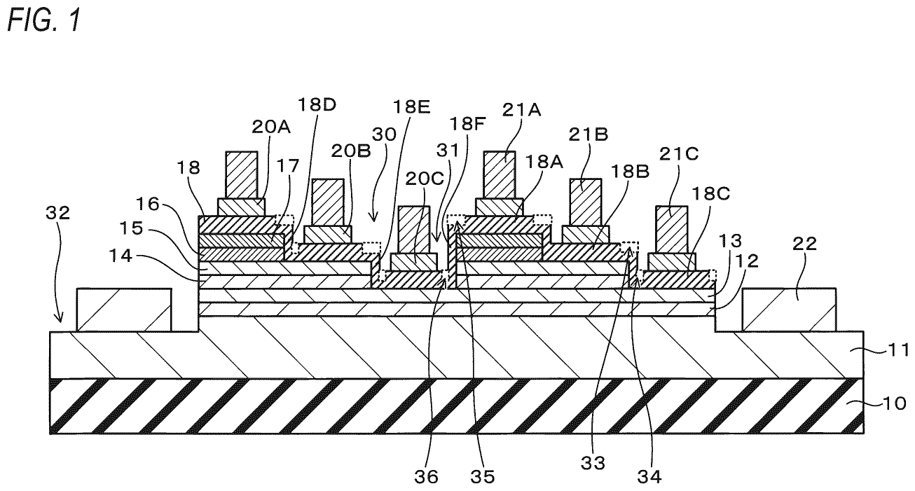

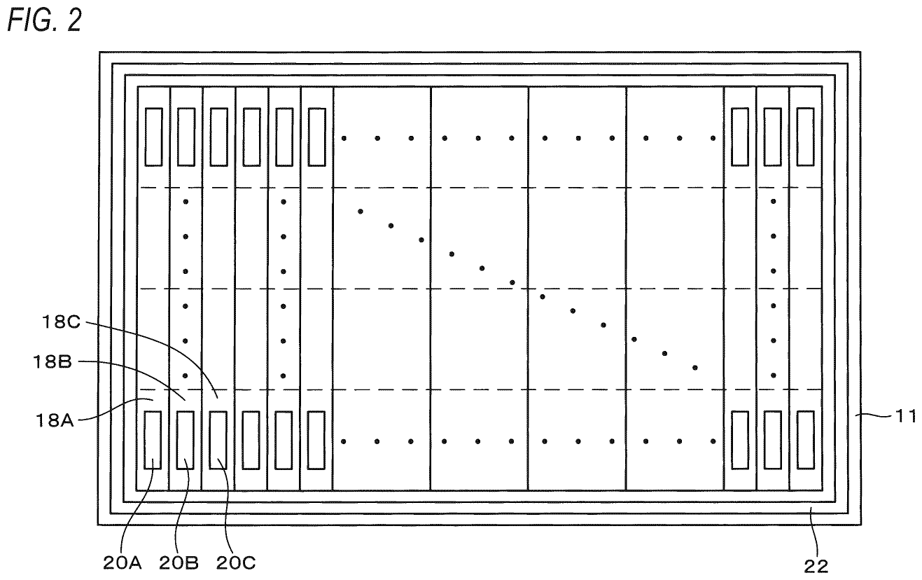

FIG. 1 is a diagram showing a configuration of a light emitting element according to an embodiment. In addition, FIG. 2 is a plan view showing an electrode pattern of the light emitting element according to the embodiment. The light emitting element according to the embodiment is a monolithic LED display. That is, a full-color light emitting unit is regarded as one pixel, the light emitting element has pixels arranged in a matrix, and the pixels are arranged on the same substrate. One pixel is composed of red, green, and blue light emitting units (sub-pixels), and light emission of these can be controlled independently, thereby making it possible to realize any desired light emission color. Note that, FIG. 1 shows a configuration for two pixels. The sub-pixel has a size of, for example, 1 μm to 100 μm.

In addition, the light emitting element according to the embodiment is a flip-chip type that extracts light from a back surface side of a substrate, and is mounted on a mounting substrate (not shown) in a face-down manner.

Note that, the light emitting element according to the embodiment is a monolithic element having a plurality of pixels on one substrate 10, but it may be an element having one pixel on one chip.

### 2. Configuration of Light Emitting Element

As shown in FIG. 1, the light emitting element according to the embodiment includes the substrate 10, an n-type layer 11, a first active layer 12, a first intermediate layer 13, a second active layer 14, a second intermediate layer 15, a third active layer 16, an electron blocking layer 17, a p-type layer 18, p-side contact electrodes 20A to 20C, p-side electrodes 21A to 21C, and an n-side electrode 22.

The substrate 10 is a growth substrate on which a Group III nitride semiconductor is grown. For example, sapphire, Si, GaN, or ScAlMgO₄ (SAM).

The n-type layer 11 is an n-type semiconductor layer provided on the substrate 10 via a low-temperature buffer layer or a high-temperature buffer layer (not shown). However, the buffer layer may be provided as necessary, and may not be provided when the substrate is GaN.

The n-type layer 11 is, for example, n-GaN, n-AlGaN, or n-InGaN. A Si concentration is, for example, 1×10¹⁸ cm⁻³ to 100×10¹⁸ cm⁻³.

The first active layer 12 is a light emitting layer having an SQW or MQW structure provided on the n-type layer 11. An emission wavelength is blue and is 430 nm to 480 nm. The first active layer 12 has a structure in which a barrier layer made of AlGaN and a well layer made of InGaN are alternately stacked for 1 to 9 pairs. The number of pairs is more preferably 1 to 7, and still more preferably 1 to 5.

A base layer may be provided between the n-type layer 11 and the first active layer 12 as necessary. The base layer is a semiconductor layer having a superlattice structure provided on the n-type layer 11, and is a layer for relaxing a lattice strain in a semiconductor layer formed on the base layer. The base layer is formed by alternately stacking Group III nitride semiconductor thin films having different compositions (for example, two of GaN, InGaN, and AlGaN), and the number of pairs is, for example, 3 to 30. The base layer may be non-doped or doped with Si by about 1×10¹⁷ cm⁻³ to 100×10¹⁷ cm⁻³. It is not necessary to have a superlattice structure as long as the strain can be relaxed.

In addition, an ESD layer may be provided between the n-type layer 11 and the base layer. The ESD layer is a layer provided to increase an electrostatic breakdown voltage. The ESD layer is, for example, non-doped or lightly Si-doped GaN, InGaN, or AlGaN.

The first intermediate layer 13 is a semiconductor layer provided on the first active layer 12. The first intermediate layer 13 is a layer provided to enable light emission from the first active layer 12 and light emission from the second active layer 14 to be separately controlled. The first intermediate layer 13 also serves to protect the first active layer 12 from etching damage when forming a second groove 31 to be described later.

The first intermediate layer 13 has a structure in which a non-doped intermediate layer and an n-type intermediate layer are sequentially stacked from a first active layer 12 side. The non-doped intermediate layer and the n-type intermediate layer may be made of the same material except for impurities. A reason why the first intermediate layer 13 has such a two-layer structure will be described later.

A material of the first intermediate layer 13 is an In-containing Group III nitride semiconductor, and is preferably InGaN, for example. With a surfactant effect of In, roughness on a surface of the first intermediate layer 13 can be prevented and surface flatness can be improved. In addition, the lattice strain can be relaxed.

It is sufficient that an In composition (a molar ratio of In to all Group III metals in the Group III nitride semiconductor) of the first intermediate layer 13 is set to have a band gap in which light emitted from the first active layer 12 and light emitted from the second active layer 14 are not absorbed. A preferred In composition is 10% or less, more preferably 5% or less, and still more preferably 2% or less. When the In composition is greater than 10%, the surface of the first intermediate layer 13 is rough. The In composition is any as long as it is greater than 0%, and may be at a doping level (a level that does not form a mixed crystal). For example, GaN having an In concentration of 1×10¹⁴ cm⁻³ or more and 1×10²² cm⁻³ or less.

In the first intermediate layer 13, the non-doped intermediate layer is non-doped, and the n-type intermediate layer is Si-doped. The n-type intermediate layer preferably has a Si concentration of 1×10¹⁷ cm⁻³ to 1000×10¹⁷ cm⁻³. It is preferably 10×10¹⁷ cm⁻³ to 100×10¹⁷ cm⁻³, and more preferably 20×10¹⁷ cm⁻³ to 80×10¹⁷ cm⁻³. The n-type intermediate layer may be modulated and doped with Si, or there may be a non-doped region in a partial region of the n-type intermediate layer.

A thickness of the first intermediate layer 13 is preferably 20 nm to 150 nm. When the thickness is more than 150 nm, the surface of the first intermediate layer 13 may be rough. When the thickness is less than 20 nm, there is a possibility that it is difficult to control a depth of the second groove 31 to be within the non-doped intermediate layer when forming the second groove 31 to be described later. The thickness is more preferably 30 nm to 100 nm, and still more preferably 50 nm to 80 nm.

In addition, a thickness of the non-doped intermediate layer of the first intermediate layer 13 is preferably 10 nm or more. This is for controlling an etching depth and avoiding etching damage to the first active layer 12. In addition, a thickness of the n-type intermediate layer of the first intermediate layer 13 is preferably 10 nm or more. This is for independently controlling light emitting characteristics of each active layer.

The second active layer 14 is a layer provided on the first intermediate layer 13, and has a quantum well structure of SQW or MQW. An emission wavelength is green and is 510 nm to 570 nm. The quantum well structure has a structure in which a barrier layer made of GaN or AlGaN and a well layer made of InGaN are alternately stacked for 1 to 7 pairs.

A strain relaxation layer may be provided between the first intermediate layer 13 and the second active layer 14. When the strain relaxation layer is provided, a strain in the second active layer 14 stacked thereon can be relaxed, and a crystal quality can be improved. The strain relaxation layer has an SQW structure or an MQW structure in which a barrier layer and a well layer are sequentially stacked, and has a quantum well structure in which a thickness of the well layer is adjusted to be small so as not to emit light. For example, when a thickness of the well layer is set to 1 nm or less, it is possible to prevent the well layer from emitting light. The barrier layer is AlGaN, and the well layer is InGaN. It is sufficient that a wavelength corresponding to a band edge energy in the well layer of the strain relaxation layer is shorter than the emission wavelength of the second active layer 14, and is, for example, 400 nm to 460 nm when the emission wavelength is 500 nm to 560 nm.

The second intermediate layer 15 is a semiconductor layer provided on the second active layer 14. The second intermediate layer 15 is provided for a reason same as that of the first intermediate layer 13, and is a layer provided to enable light emission from the second active layer 14 and light emission from the third active layer 16 to be separately controlled. In addition, it also has a role of protecting the second active layer 14 from etching damage when forming a first groove 30 to be described later.

The second intermediate layer 15 has a structure in which a non-doped intermediate layer and an n-type intermediate layer are sequentially stacked from a second active layer 14 side. The non-doped intermediate layer and the n-type intermediate layer have a structure same as that of the non-doped intermediate layer and the n-type intermediate layer of the first intermediate layer 13. That is, the non-doped intermediate layer and the n-type intermediate layer of the second intermediate layer 15 are made of a material same as that of the non-doped intermediate layer and the n-type intermediate layer of the first intermediate layer 13 except for impurities, and a thickness range is also the same. In the second intermediate layer 15, the non-doped intermediate layer is non-doped, and the n-type intermediate layer is Si-doped. A Si concentration in the n-type intermediate layer of the second intermediate layer 15 is in a range same as the Si concentration in the n-type intermediate layer of the first intermediate layer 13, and may be the same concentration.

The third active layer 16 is a layer provided on the second intermediate layer 15, and has a quantum well structure of SQW or MQW. An emission wavelength is red and is 590 nm to 700 nm. The quantum well structure has a structure in which a barrier layer made of InGaN and a well layer made of InGaN are alternately stacked for 1 to 7 pairs. The number of pairs is more preferably 1 to 5, and still more preferably 1 to 3.

A strain relaxation layer may be provided between the second intermediate layer 15 and the third active layer 16. When the strain relaxation layer is provided, a strain in the third active layer 16 stacked thereon can be relaxed, and the crystal quality can be improved. The strain relaxation layer has, for example, a structure in which a first strain relaxation layer and a second strain relaxation layer are sequentially stacked from a second intermediate layer 15 side.

The first strain relaxation layer and the second strain relaxation layer have a structure same as the strain relaxation layer between the first intermediate layer 13 and the second active layer 14 described above. A wavelength corresponding to a band edge energy in a well layer of the first strain relaxation layer is, for example, 400 nm to 460 nm. In the second strain relaxation layer, a wavelength corresponding to a band edge energy in a well layer of the second strain relaxation layer is, for example, 510 nm to 570 nm.

The electron blocking layer 17 is a semiconductor layer provided on the third active layer 16. The electron blocking layer 17 is a layer for blocking electrons implanted from the n-type layer 11 in order to efficiently confine the electrons in the third active layer 16. In addition, the electron blocking layer 17 is layer not only having an electron blocking function but also functioning as a protective layer for protecting the third active layer 16. The electron blocking layer 17 may be made of a material having a band gap wider than that of the well layer of the third active layer 16, such as AlGaN, GaN, or InGaN. A thickness of the electron blocking layer 17 is preferably 2.5 nm to 50 nm, and more preferably 5 nm to 25 nm. The electron blocking layer 17 may be doped with impurities or Mg. In this case, a Mg concentration is preferably 1×10¹⁸ cm⁻³ to 1000×10¹⁸ cm⁻³.

A partial region on a surface of the electron blocking layer 17 is etched to provide grooves, and from the electron blocking layer 17, the first groove 30 reaching the second intermediate layer 15, the second groove 31 reaching the first intermediate layer 13, and a third groove 32 reaching the n-type layer 11 are provided.

The first groove 30 has a depth reaching the non-doped intermediate layer of the second intermediate layer 15. In this way, by removing the n-type intermediate layer of the second intermediate layer 15 below the p-side electrode 21B, the n-type intermediate layer is not positioned on the second active layer 14, and the second active layer 14 emits light. The second groove 31 has a depth reaching the non-doped intermediate layer of the first intermediate layer 13. For the same reason, by removing the n-type intermediate layer of the first intermediate layer 13 below the p-side electrode 21C, the n-type intermediate layer is not positioned on the first active layer 12, and the first active layer 12 emits light.

The p-type layer 18 is a semiconductor layer provided continuously in the form of a film on the electron blocking layer 17, on a side surface and a bottom surface of the first groove 30, and on a side surface and a bottom surface of the second groove 31. In the p-type layer 18, a region on the electron blocking layer 17 is defined as a region 18A, a region on the bottom surface of the first groove 30 (on the second intermediate layer 15) is defined as a region 18B, and a region on the bottom surface of the second groove 31 (on the first intermediate layer 13) is defined as a region 18C. In addition, in the p-type layer 18, a region that connects the region 18A and the region 18B is defined as a region 18D, a region that connects the region 18B and the region 18C is defined as a region 18E, and a region that connects the region 18C and the region 18A is defined as a region 18F. The p-type layer 18 is composed of a second electron blocking layer, a first layer, and a second layer sequentially from an electron blocking layer 17 side.

The second electron blocking layer is provided on the electron blocking layer 17, on the non-doped intermediate layer exposed on the bottom surface of the first groove 30, and on the non-doped intermediate layer exposed on the bottom surface of the second groove 31, and is a layer for blocking electrons implanted from the n-type layer 11 in order to efficiently confine the electrons in the first active layer 12, the second active layer 14, and the third active layer 16.

The second electron blocking layer may be a single layer of GaN or AlGaN, a structure in which two or more of AlGaN, GaN, and InGaN are stacked, or a structure in which they are stacked with only a composition ratio changed. Alternatively, the second electron blocking layer may have a superlattice structure. Having a superlattice structure, the electrons can be more efficiently blocked. The superlattice structure is, for example, a structure in which p-AlGaN and p-InGaN are alternately stacked, or a structure in which p-AlGaN and p-GaN are alternately stacked.

A thickness of the second electron blocking layer is preferably 5 nm to 50 nm, and more preferably 5 nm to 25 nm. In addition, the second electron blocking layer is of a Mg-doped p-type. When the second electron blocking layer is of a p-type, holes can be efficiently implanted into the active layer. In addition, a larger barrier can be provided to electrons, and an electron blocking function can be improved. The second electron blocking layer may be non-doped for the reasons described above, and is preferably doped with Mg to be of a p-type. A Mg concentration in the second electron blocking layer is preferably 1×10¹⁹ cm⁻³ to 100×10¹⁹ cm⁻³.

The first layer is preferably p-GaN or p-InGaN. A thickness of the first layer is preferably 10 nm to 500 nm, more preferably 10 nm to 200 nm, and still more preferably 10 nm to 100 nm. A Mg concentration in the first layer is preferably 1×10¹⁹ cm⁻³ to 100×10¹⁹ cm⁻³. The second layer is preferably p-GaN or p-InGaN. A thickness of the second layer is preferably 2 nm to 50 nm, more preferably 4 nm to 20 nm, and still more preferably 6 nm to 10 nm. A Mg concentration in the second layer is preferably 1×10²⁰ cm⁻³ to 100×10²⁰ cm⁻³.

In the p-type layer 18, a region in a vicinity of the side surface of the first groove 30, that is, a region in a vicinity of the region 18D as a region that connects the region 18A and the region 18B, is provided with a recessed portion. The recessed portion is provided on an upper stage side (region 18A side) and a lower stage side (region 18B side), with the recessed portion on the upper stage side being designated as 33 and the recessed portion on lower stage side being designated as 34. The recessed portions 33 and 34 are second recessed portions. Similarly, the recessed portions 33 and 34 are provided in a region in a vicinity of the region 18E as a region that connects the region 18B and the region 18C. These recessed portions are first recessed portions.

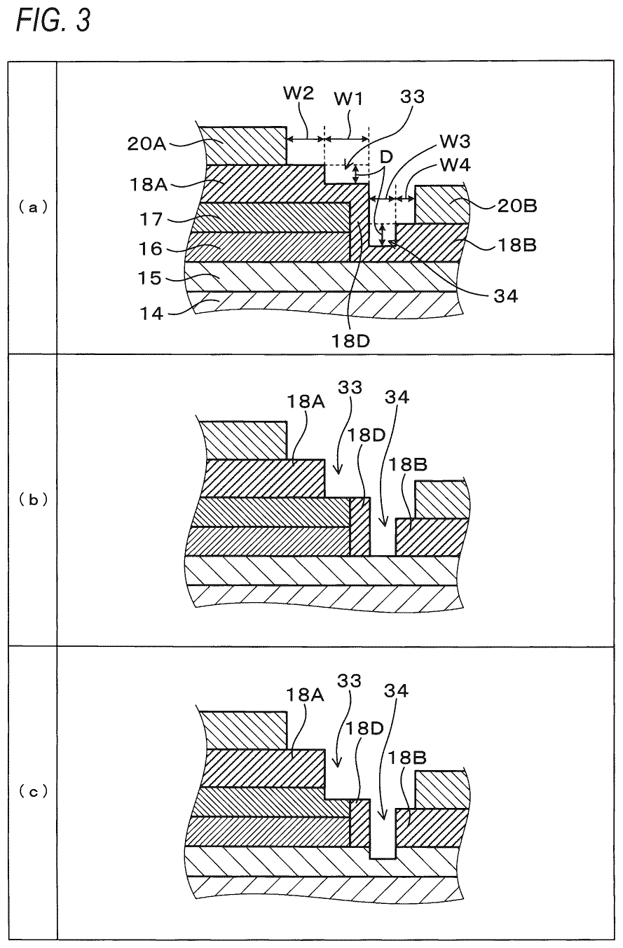

The recessed portion 33 and the recessed portion 34 are formed in the same etching step and therefore have the same depth. A depth D of the recessed portions 33 and 34 may be in a range in which the electron blocking layer 17 and the second intermediate layer 15 are not exposed (bottom surfaces of the recessed portions 33 and 34 are in a range of the p-type layer 18), as shown in (a) of FIG. 3. That is, the depth D may be in a range smaller than a thickness of the p-type layer 18. In addition, as shown in (b) of FIG. 3, the depth D may be a depth at which the surface of the electron blocking layer 17 and a surface of the second intermediate layer 15 are just exposed. That is, the depth D may be equal to the thickness of the p-type layer 18. In addition, as shown in (c) of FIG. 3, the depth D may be deeper than the surface of the electron blocking layer 17 and the surface of the second intermediate layer 15 (that is, the depth D is greater than the thickness of the p-type layer 18), and may be within a range in which the third active layer 16 and the second active layer 14 are not exposed. Note that, as long as the depth is within the above range, the recessed portion 33 and the recessed portion 34 may have different depths.

It is most preferable that the depth D of the recessed portion 33 and the recessed portion 34 is in the state as shown in (b) of FIG. 3, that is, the depth D is equal to the thickness of the p-type layer 18. Current leakage between the region 18A and the region 18B and between the region 18B and the region 18C can be sufficiently prevented. Considering a variation in etching depth, the state does not have to be exactly as shown in (b) of FIG. 3, and an error of about −20 nm to +20 nm of the thickness of the p-type layer 18 is acceptable. More preferably, it is in the range of −10 nm to +10 nm of the thickness of the p-type layer 18.

Note that, it is not necessary to provide both the recessed portions 33 and 34, and only one of them may be provided. However, in order to sufficiently electrically isolate the region 18A from the region 18B, and the region 18B from the region 18C, it is preferable to provide both.

As shown in (a) of FIG. 3, a width of the recessed portion 33 is defined as W1, and a distance from the recessed portion 33 to the p-side contact electrode 20A is defined as W2. In this case, W1 is preferably set to 0.1 μm to 2 μm. Resistance of the p-type layer 18 in a region where the recessed portion 33 is provided can be sufficiently increased. In addition, W2 is preferably set to 0 μm to 2 μm. Similarly, the resistance of the p-type layer 18 can be sufficiently increased. In addition, a width of the recessed portion 34 is defined as W3, and a distance from the recessed portion 34 to the p-side contact electrode 20B is defined as W4. In this case, W3 is preferably set in the same range as W1. In addition, W4 is preferably set in the same range as W2.

In addition, a recessed portion is provided in a region in a vicinity of the region 18F as a region that connects the region 18C and the region 18A. The recessed portion is provided on an upper stage side (region 18A side) and a lower stage side (region 18C side), with the recessed portion on the upper stage side being designated as 35 and the recessed portion on lower stage side being designated as 36. The recessed portions 35 and 36 are third recessed portions.

A depth and a width of the recessed portions 35 and 36, a distance from the recessed portion 35 to the p-side contact electrode 20A, and a distance from the recessed portion 36 to the p-side contact electrode 20C are preferably in the same ranges as those of the recessed portions 33 and 34. In addition, only one of the recessed portions 35 and 36 may be provided.

When the recessed portions 33 to 36 having the depth D shown in (a) of FIG. 3 are provided, the p-type layer 18 in regions where the recessed portions 33 to 36 are provided is thinner, and the resistance is increased. In addition, when the recessed portions 33 to 36 having the depth D shown in (b) and (c) of FIG. 3 are provided, the region 18A and the region 18B, the region 18B and the region 18C, and the region 18C and the region 18A are physically separated from each other. Therefore, when a certain sub-pixel is intended to emit light, it is possible to prevent the current from leaking through the p-type layer 18 and prevent an adjacent sub-pixel from emitting light.

The p-side contact electrodes 20A to 20C are electrodes provided on the region 18A, the region 18B, and the region 18C, respectively. A material of the p-side contact electrodes 20A to 20C is a transparent electrode such as ITO or IZO.

The p-side electrodes 21A to 21C are electrodes provided on the p-side contact electrodes 20A to 20C, respectively. A material of the p-side electrodes 21A to 21C is, for example, Ti/Au. In addition, a metal having a high reflectance may be provided at an interfaces between the p-side electrodes 21A to 21C and the p-side contact electrodes 20A to 20C. For example, Ag, Al, Rh, or Ru.

Note that, by using a material that can be brought into contact with the p-type layer 18 at low resistance and that has a high reflectance as the material of the p-side contact electrodes 20A to 20C, the p-side electrodes 21A to 21C may be omitted.

The n-side electrode 22 is an electrode provided on the n-type layer 11 exposed on a bottom surface of the third groove 32. When the substrate 10 is made of a conductive material, the n-side electrode 22 may be provided on a back surface of the substrate 10 without providing the third groove 32. A material of the n-side electrode 22 is, for example, Ti/Al or V/Al.

As described above, in the light emitting element according to the embodiment, the recessed portions 33 to 36 are provided in the p-type layer 18 in the regions in the vicinity of the regions 18D to 18F. Therefore, the p-type layer 18 is thin and the resistance is increased in the regions of the recessed portions 33 to 36. Alternatively, the regions 18A to 18C are physically separated from each other. Therefore, when a certain sub-pixel is intended to emit light, it is possible to prevent the current from leaking through the p-type layer 18 and prevent an adjacent sub-pixel from emitting light. Therefore, with the light emitting element according to the embodiment, it is possible to prevent unintended display on the display and a decrease in color purity.

### 3. Planar Pattern of Light Emitting Element

FIG. 2 is a plan view showing a planar pattern of the light emitting element according to the embodiment. As shown in FIG. 2, the light emitting element has a rectangular shape in a plan view, and the n-side electrode 22 is provided in a shape of a rectangular ring along an outer periphery. The first groove 30 and the second groove 31 are alternately provided in a stripe, and the p-side contact electrodes 20A to 20C are provided in the stripe regions, respectively. In addition, the p-side contact electrodes 20A to 20C are arranged periodically in a stripe direction. The regions of the p-side contact electrodes 20A to 20C become a red sub-pixel, a green sub-pixel, and a blue sub-pixel, respectively. In this way, one pixel emitting three colors is arranged in a lattice pattern, and one pixel is further divided into three stripe-like regions to form sub-pixels emitting red, green, and blue light, respectively. That is, the light emitting element according to the embodiment is a monolithic micro LED display.

Here, since the p-type layer 18 has the recessed portions 33 to 36 as shown in FIG. 1 and FIG. 3, when a certain sub-pixel is intended to emit light, it is possible to prevent the adjacent sub-pixel from emitting light. The effect of the recessed portions 33 to 36 is remarkable when the size of the sub-pixel is 10 μm or less, particularly 3 μm or less. When the sub-pixel is small, a distance between the p-side contact electrodes 20A to 20C is shorter, and current leakage through the p-type layer 18 increases. However, this can be effectively prevented by providing the recessed portions 33 to 36.

Note that, the planar pattern of the sub-pixels (the planar pattern of the first groove 30 and the second groove 31 and the planar pattern of the p-side contact electrodes 20A to 20C) is not limited to this. For example, a 2×2 lattice pattern may be used, with two of the sub-pixels being red light emitting sub-pixels and the remaining sub-pixels being green light emitting sub-pixels and blue light emitting sub-pixels.

### 4. Steps of Producing Light Emitting Element

Next, steps of producing the light emitting element according to the embodiment will be described with reference to the drawings.

First, the substrate 10 is prepared, and the substrate is subjected to a heat treatment by adding hydrogen, nitrogen, and, if necessary, ammonia.

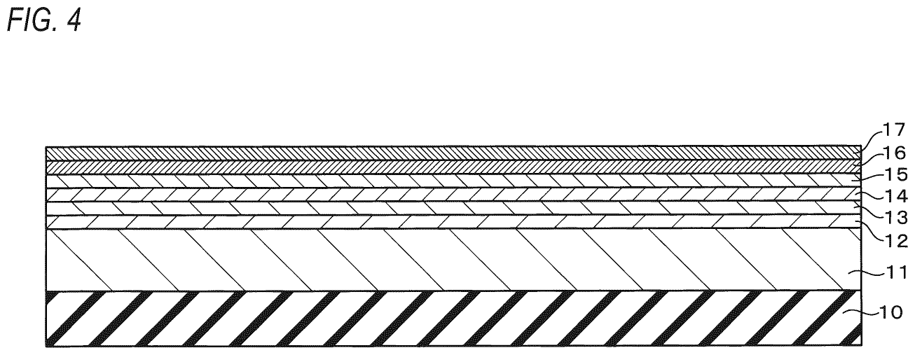

Next, a buffer layer is formed on the substrate 10, and the n-type layer 11, the first active layer 12, the first intermediate layer 13, the second active layer 14, the second intermediate layer 15, the third active layer 16, the electron blocking layer 17, and the p-type layer 18 are sequentially formed on the buffer layer (see FIG. 4). Each layer is formed by using a MOCVD method.

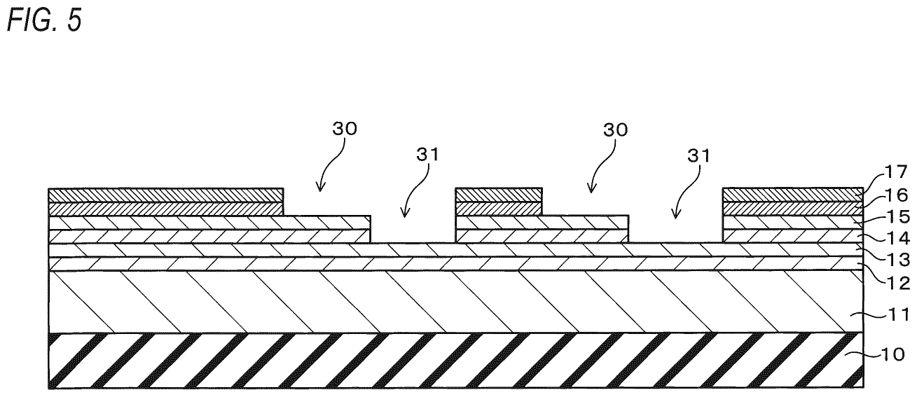

Next, a partial region on a surface of the p-type layer 18 is dry-etched until it reaches the non-doped intermediate layer of the second intermediate layer 15 to form the first groove 30, and is dry-etched until it reaches the non-doped intermediate layer of the first intermediate layer 13 to form the second groove 31 (see FIG. 5).

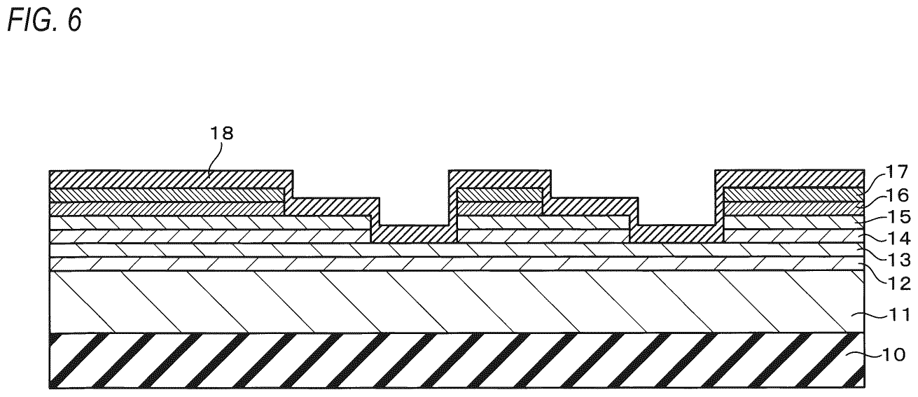

Next, the p-type layer 18 is formed continuously on the electron blocking layer 17, on the non-doped intermediate layer of the second intermediate layer 15 exposed by the first groove 30, and on the non-doped intermediate layer of the first intermediate layer 13 exposed by the second groove 31 (see FIG. 6). Note that, the p-type layer 18 is not of p-type at this stage, but is referred to as p-type since it will be of p-type later.

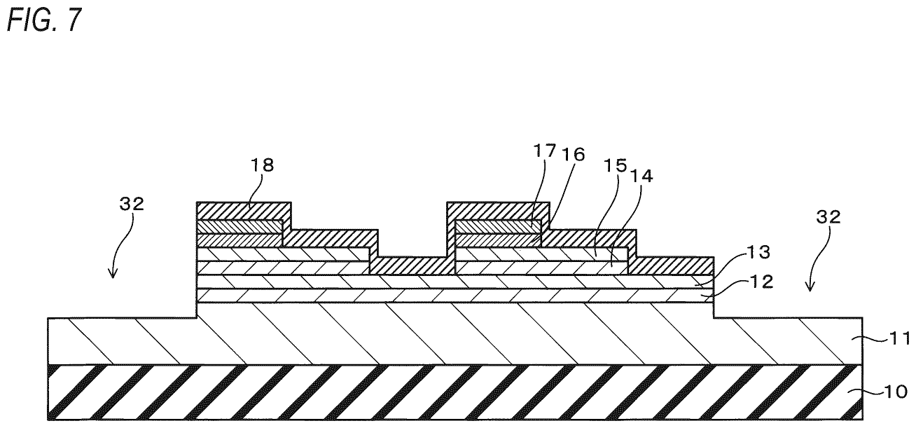

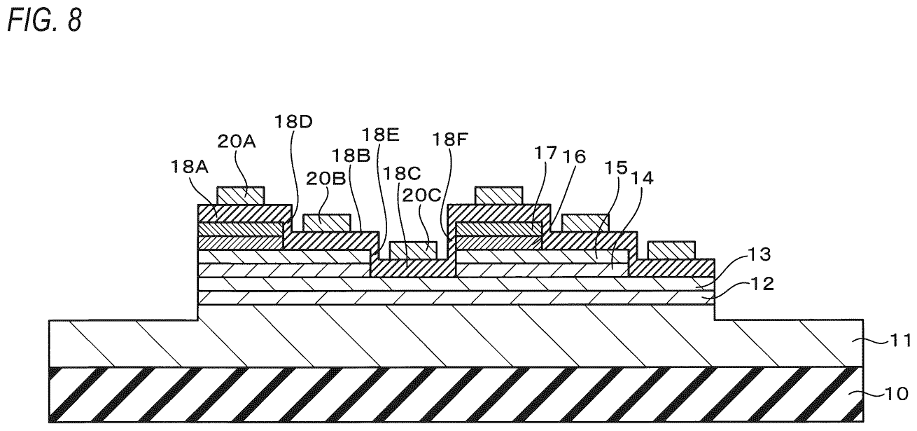

Next, a partial region on the surface of the p-type layer 18 is dry-etched until it reaches the n-type layer 11 to form the third groove 32 (see FIG. 7). Then, the p-side contact electrodes 20A to 20C are formed at predetermined positions (on the regions 18A to 18C) on the p-type layer 18, respectively (see FIG. 8).

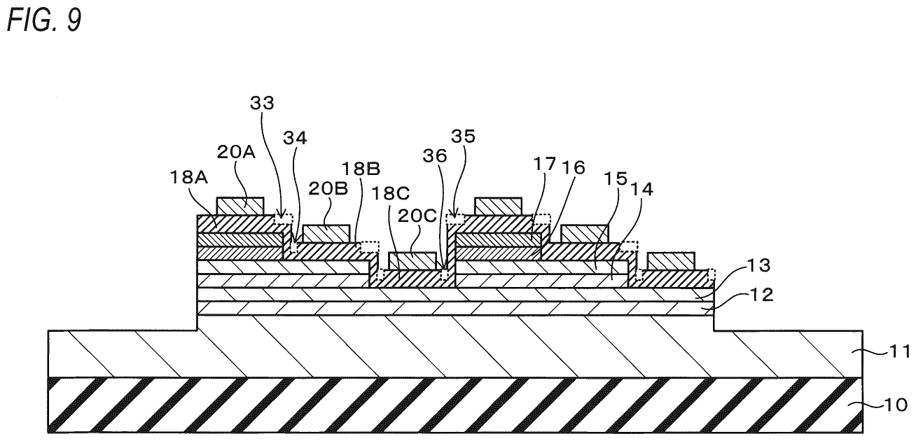

Next, the p-type layer 18 is dry-etched in a region in the vicinity of the region 18D, in a region in the vicinity of the region 18E, and in a region in the vicinity of the region 18F to form the recessed portions 33 to 36 (see FIG. 9). The depth D of the recessed portions 33 to 36 is preferably set to be the same as the thickness of the p-type layer 18, and the surfaces of the electron blocking layer 17, the second intermediate layer 15, and the first intermediate layer 13 are preferably exposed on the bottom surfaces of the recessed portions 33 to 36. Note that, the recessed portions 33 to 36 may be formed before the third groove 32 is formed or before the p-side contact electrodes 20A to 20C are formed.

Thereafter, the n-side electrode 22 is formed on the n-type layer 11 exposed on the bottom surface of the third groove 32, and the p-side electrodes 21A to 21C are formed on the p-side contact electrodes 20A to 20C, respectively. With the above, the light emitting element according to the embodiment is produced.

As described above, in the method for producing a light emitting element according to the embodiment, since the recessed portions 33 to 36 are formed by etching predetermined regions of the p-type layer 18, the p-type layer 18 is thinner in the region where the recessed portions 33 to 36 are formed, and the resistance is increased. Alternatively, the regions 18A to 18C are physically separated from each other. Therefore, when a certain sub-pixel is intended to emit light, it is possible to prevent current leakage to other adjacent sub-pixels through the p-type layer 18. As a result, only a desired sub-pixel can emit light, and the color purity can be improved.

### 5. Experiment Results

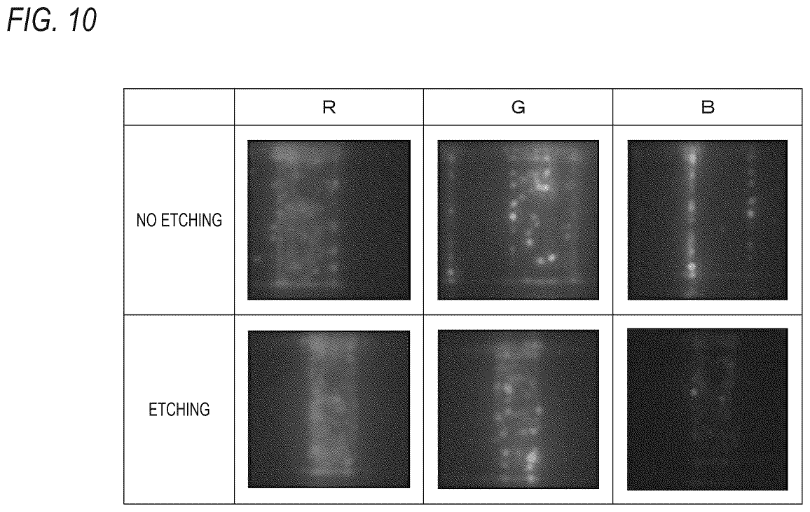

A light emitting element in which the p-type layer 18 was etched to provide the recessed portions 33 to 36 as in the embodiment (light emitting element in Example 1) and a light emitting element in which the p-type layer 18 was not etched and the recessed portions 33 to 36 were not provided (light emitting element in Comparative Example) were prepared, and light emission states of the sub-pixel were compared. FIG. 10 is a photograph showing the light emission states of the sub-pixels. In FIG. 10, R indicates a red light emitting sub-pixel, G indicates a green light emitting sub-pixel, and B indicates a blue light emitting sub-pixel.

As shown FIG. 10, in the light emitting element in Comparative Example, when a green light emitting sub-pixel is made to emit light, red light is observed from an adjacent sub-pixel. In addition, when a blue light emitting sub-pixel is made to emit light, green light is observed from an adjacent sub-pixel. This is thought to be because a drive voltage is lower for green light emission than for blue light emission, and lower for red light emission than for green light emission.

In contrast, in the light emitting element in Example 1, no emission of light from adjacent sub-pixels is observed regardless of whether the red, green, or blue sub-pixel is made to emit light. As seen from this result, when the recessed portions 33 to 36 are provided in the p-type layer 18, current leakage to adjacent sub-pixels can be prevented, making it possible to precisely cause only the desired sub-pixel to emit light.

### Modification of Embodiment

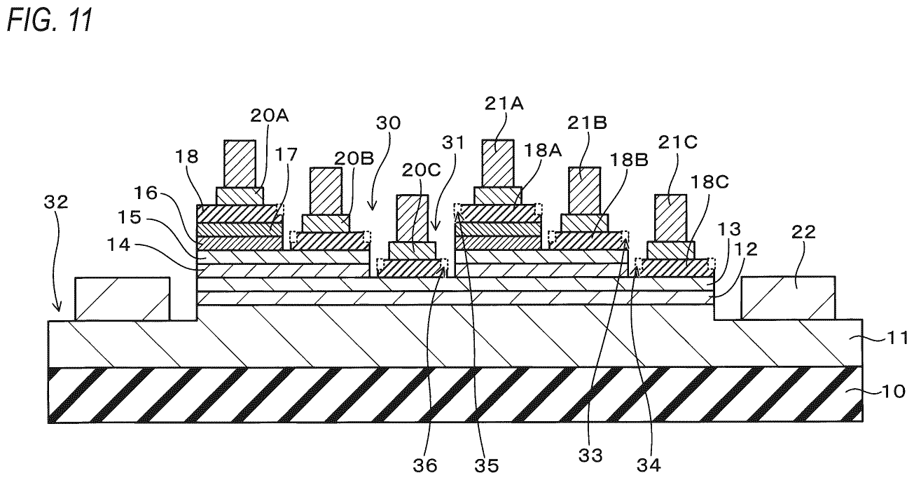

In this embodiment, the side surface of the first groove 30 and the side surface of the second groove 31 have the regions 18D to 18F, which are not removed when the recessed portions 33 to 36 are formed. With the regions 18D to 18F remaining, non-light-emission recombination on the side surface of the first groove 30 and the side surface of the second groove 31 may be prevented. However, when the recessed portions 33 to 36 are formed, the regions 18D to 18F may also be removed by etching as shown in FIG. 11. Although the effect of preventing non-light-emission recombination is lost, the regions 18A to 18C are physically separated from each other, so that current leakage to adjacent sub-pixels can be further prevented. In addition, the regions 18D to 18F may be thinner than the regions 18A to 18C due to the etching performed when the recessed portions 33 to 36 are formed. The resistance of the regions 18D to 18F can be increased, and the current leakage can be further prevented.

In addition, in the embodiment, the light is emitted in three colors, red, green, and blue, but the present invention is not limited to this, and it is sufficient that the light is emitted in two or more colors with different emission wavelengths. For example, the light may also be emitted in four colors, red, yellow, green, and blue.

The light emitting element according to the embodiment is a monolithic LED display, but the present invention can also be applied to a simple three-color LED instead of this display.

The light emitting element according to the embodiment can be used in display devices such as a display, and wavelength division multiplexing communications.

### REFERENCE SIGNS LIST

10: substrate
11: n-type layer
12: first active layer
13: first intermediate layer
14: second active layer
15: second intermediate layer
16: third active layer
17: electron blocking layer
18: p-type layer
18A to 18F: region
20A to 20C: p-side contact electrode
21A to 21C: p-side electrode
22: n-side electrode
30: first groove
31: second groove
32: third groove
33, 34: recessed portion (first recessed portion, second recessed portion)
35, 36: recessed portion (third recessed portion)

What is claimed is:

1. A method for producing a light emitting element, comprising:
forming, over a substrate, an n-type layer containing an n-type Group III nitride semiconductor;
forming, over the n-type layer, a first active layer having a predetermined band gap energy;
forming, over the first active layer, a first intermediate layer containing a Group III nitride semiconductor;
forming, over the first intermediate layer, a second active layer having a band gap energy different from the band gap energy of the first active layer;
forming a first groove having a depth reaching the first intermediate layer from a side of the second active layer;
forming a p-type layer containing a p-type Group III nitride semiconductor over the second active layer, over a bottom surface of the first groove, and over a side surface of the first groove; and
etching the p-type layer in a vicinity of a region of the p-type layer that connects a region of the p-type layer over the second active layer and a region of the p-type layer over the bottom surface of the first groove to form a first recessed portion.

2. The method for producing a light emitting element according to claim 1, wherein the first recessed portion has a depth smaller than a thickness of the p-type layer.

3. The method for producing a light emitting element according to claim 1, wherein
the first recessed portion has a depth in a range of −20 nm to +20 nm of a thickness of the p-type layer.

4. The method for producing a light emitting element according to claim 1, further comprising:
forming, over the second active layer, a second intermediate layer containing a Group III nitride semiconductor;
forming, over the second intermediate layer, a third active layer having a band gap energy different from the band gap energy of the first active layer and different from the band gap energy of the second active layer; and
forming a second groove having a depth reaching the second intermediate layer from a side of the third active layer, wherein
in the forming of the p-type layer, the p-type layer containing a p-type Group III nitride semiconductor is formed over the third active layer, over the bottom surface of the first groove, over a bottom surface of the second groove, over the side surface of the first groove, and over a side surface of the second groove, and
in the etching of the p-type layer, the p-type layer is etched in a vicinity of a region of the p-type layer that connects a region of the p-type layer over the third active layer and a region of the p-type layer over the bottom surface of the second groove to further form a second recessed portion having a depth same as the first recessed portion.

5. The method for producing a light emitting element according to claim 2, further comprising:
forming, over the second active layer, a second intermediate layer containing a Group III nitride semiconductor;
forming, over the second intermediate layer, a third active layer having a band gap energy different from the band gap energy of the first active layer and different from the band gap energy of the second active layer; and
forming a second groove having a depth reaching the second intermediate layer from a side of the third active layer, wherein
in the forming of the p-type layer, the p-type layer containing a p-type Group III nitride semiconductor is formed over the third active layer, over the bottom surface of the first groove, over a bottom surface of the second groove, over the side surface of the first groove, and over a side surface of the second groove, and
in the etching of the p-type layer, the p-type layer is etched in a vicinity of a region of the p-type layer that connects a region of the p-type layer over the third active layer and a region of the p-type layer over the bottom surface of the second groove to further form a second recessed portion having a depth same as the first recessed portion.

6. The method for producing a light emitting element according to claim 3, further comprising:
forming, over the second active layer, a second intermediate layer containing a Group III nitride semiconductor;
forming, over the second intermediate layer, a third active layer having a band gap energy different from the band gap energy of the first active layer and different from the band gap energy of the second active layer; and
forming a second groove having a depth reaching the second intermediate layer from a side of the third active layer, wherein
in the forming of the p-type layer, the p-type layer containing a p-type Group III nitride semiconductor is formed over the third active layer, over the bottom surface of the first groove, over a bottom surface of the second groove, over the side surface of the first groove, and over a side surface of the second groove, and
in the etching of the p-type layer, the p-type layer is etched in a vicinity of a region of the p-type layer that connects a region of the p-type layer over the third active layer and a region of the p-type layer over the bottom surface of the second groove to further form a second recessed portion having a depth same as the first recessed portion.

7. The method for producing a light emitting element according to claim 4, wherein in the etching of the p-type layer, the p-type layer is etched in a vicinity of a region of the p-type layer that connects a region of the p-type layer over the bottom surface of the first groove and the region of the p-type layer over the third active layer to further form a third recessed portion having a depth same as the first recessed portion and the second recessed portion.

8. The method for producing a light emitting element according to claim 5, wherein in the etching of the p-type layer, the p-type layer is etched in a vicinity of a region of the p-type layer that connects a region of the p-type layer over the bottom surface of the first groove and the region of the p-type layer over the third active layer to further form a third recessed portion having a depth same as the first recessed portion and the second recessed portion.

9. The method for producing a light emitting element according to claim 6, wherein in the etching of the p-type layer, the p-type layer is etched in a vicinity of a region of the p-type layer that connects a region of the p-type layer over the bottom surface of the first groove and the region of the p-type layer over the third active layer to further form a third recessed portion having a depth same as the first recessed portion and the second recessed portion.

10. Alight emitting element comprising:
a substrate;
an n-type layer provided over the substrate and containing an n-type Group III nitride semiconductor;
a first active layer provided over the n-type layer and having a predetermined band gap energy;
a first intermediate layer provided over the first active layer and containing a Group III nitride semiconductor;
a second active layer provided over the first intermediate layer and having a band gap energy different from the band gap energy of the first active layer;
a first groove having a depth reaching the first intermediate layer from a side of the second active layer;
a p-type layer provided over the second active layer, over a bottom surface of the first groove, and over a side surface of the first groove, and containing a p-type Group III nitride semiconductor; and
a first recessed portion provided at the p-type layer in a vicinity of a region of the p-type layer that connects a region of the p-type layer over the second active layer and a region of the p-type layer over the bottom surface of the first groove.

11. The light emitting element according to claim 10, wherein the first recessed portion has a depth smaller than a thickness of the p-type layer.

12. The light emitting element according to claim 10, wherein the first recessed portion has a depth in a range of −20 nm to +20 nm of a thickness of the p-type layer.

13. The light emitting element according to claim 10, further comprising:
a second intermediate layer provided over the second active layer and containing a Group III nitride semiconductor;
a third active layer provided over the second intermediate layer and having a band gap energy different from the band gap energy of the first active layer and different from the band gap energy of the second active layer; and
a second groove having a depth reaching the second intermediate layer from a side of the third active layer, wherein
the p-type layer is provided over the third active layer, over the bottom surface of the first groove, over a bottom surface of the second groove, over the side surface of the first groove, and over a side surface of the second groove, and
a second recessed portion having a depth same as the first recessed portion is further provided at the p-type layer in a vicinity of a region of the p-type layer that connects a region of the p-type layer over the third active layer and a region of the p-type layer over the bottom surface of the second groove.

14. The light emitting element according to claim 11, further comprising:
a second intermediate layer provided over the second active layer and containing a Group III nitride semiconductor;
a third active layer provided over the second intermediate layer and having a band gap energy different from the band gap energy of the first active layer and different from the band gap energy of the second active layer; and
a second groove having a depth reaching the second intermediate layer from a side of the third active layer, wherein
the p-type layer is provided over the third active layer, over the bottom surface of the first groove, over a bottom surface of the second groove, over the side surface of the first groove, and over a side surface of the second groove, and
a second recessed portion having a depth same as the first recessed portion is further provided at the p-type layer in a vicinity of a region of the p-type layer that connects a region of the p-type layer over the third active layer and a region of the p-type layer over the bottom surface of the second groove.

15. The light emitting element according to claim 12, further comprising:
a second intermediate layer provided over the second active layer and containing a Group III nitride semiconductor;
a third active layer provided over the second intermediate layer and having a band gap energy different from the band gap energy of the first active layer and different from the band gap energy of the second active layer; and
a second groove having a depth reaching the second intermediate layer from a side of the third active layer, wherein
the p-type layer is provided over the third active layer, over the bottom surface of the first groove, over a bottom surface of the second groove, over the side surface of the first groove, and over a side surface of the second groove, and
a second recessed portion having a depth same as the first recessed portion is further provided at the p-type layer in a vicinity of a region of the p-type layer that connects a region of the p-type layer over the third active layer and a region of the p-type layer over the bottom surface of the second groove.

16. The light emitting element according to claim 13, wherein a third recessed portion having a depth same as the first recessed portion and the second recessed portion is further provided at the p-type layer in a vicinity of a region of the p-type layer that connects the region of the p-type layer over the bottom surface of the first groove and the region of the p-type layer over the third active layer.

17. The light emitting element according to claim 14, wherein a third recessed portion having a depth same as the first recessed portion and the second recessed portion is further provided at the p-type layer in a vicinity of a region of the p-type layer that connects the region of the p-type layer over the bottom surface of the first groove and the region of the p-type layer over the third active layer.

18. The light emitting element according to claim 15, wherein a third recessed portion having a depth same as the first recessed portion and the second recessed portion is further provided at the p-type layer in a vicinity of a region of the p-type layer that connects the region of the p-type layer over the bottom surface of the first groove and the region of the p-type layer over the third active layer.
